(19) United States
(12) Patent Application Publication
(10) Pub. No.: US 2016/0307979 A1
(43) Pub. Date: Oct. 20, 2016

(54) THIN-FILM TRANSISTOR SUBSTRATE, DISPLAY APPARATUS INCLUDING THE SAME, METHOD OF MANUFACTURING A THIN-FILM TRANSISTOR SUBSTRATE, AND METHOD OF MANUFACTURING A DISPLAY APPARATUS

(71) Applicant: SAMSUNG DISPLAY CO, LTD., YONGIN-SI (KR)

(72) Inventor: JAEHYUN LEE, YONGIN-SI (KR)

(21) Appl. No.: 14/932,107

(22) Filed: Nov. 4, 2015

(30) Foreign Application Priority Data
Apr. 14, 2015 (KR) 10-2015-0052457

(51) Int. Cl. H01L 27/32; G09G 3/3225; H01L 29/66; G09G 3/3275; H01L 29/786; H01L 51/05

(52) U.S. Cl. CPC H01L 27/3262; H01L 29/78666; H01L 29/78675; H01L 51/0541; H01L 29/66757; H01L 27/3248; H01L 27/3274; H01L 27/3276; G09G 3/3275; G09G 3/3225; H01L 2227/323; G09G 2300/0814

(57) ABSTRACT

A thin-film transistor (TFT) substrate includes a substrate, a first TFT disposed on the substrate and a second TFT disposed on the substrate. The first TFT includes a first active pattern having a first hydrogen density and a first gate electrode overlapping a portion of the first active pattern. The second TFT includes a second active pattern having a second hydrogen density higher than the first hydrogen density and a second gate electrode overlapping a portion of the second active pattern.

### CROSS-REFERENCE TO RELATED APPLICATION

This application claims priority under 35 U.S.C. §119 to Korean Patent Application No. 10-2015-0052457, filed on Apr. 14, 2015, in the Korean Intellectual Property Office, the disclosure of which is incorporated by reference herein in its entirety.

### TECHNICAL FIELD

Exemplary embodiments of the present invention relate to a thin-film transistor (TFT) substrate, a display apparatus including the same, a method of manufacturing the TFT substrate, and a method of manufacturing the display apparatus. More particularly, exemplary embodiments of the present invention relate to a TFT substrate capable of adjusting characteristics of the TFT substrate according to functions of TFTs, a display apparatus including the same, a method of manufacturing the TFT substrate, and a method of manufacturing the display apparatus.

### DISCUSSION OF THE RELATED ART

In general, a TFT substrate includes a structure in which one or more TFTs, capacitors, and the like, are formed on a substrate. A display apparatus, and the like, may be manufactured using the TFT substrate.

A TFT in the TFT substrate includes a crystalline silicon layer as an active layer. The crystalline silicon layer is formed by crystalizing an amorphous silicon layer. The characteristics of the TFT are determined according to a crystalizing method, an environment in which the TFT is disposed, and the like. A required characteristic range of a TFT varies according to a role of the TFT in a circuit.

However, in existing TFT substrates it is not easy to adjust the characteristics of the TFT substrate according to a role of a TFT disposed thereon. This may cause a problem in a display apparatus including the TFT substrate, for example, an image of non-uniform brightness is displayed even when a same electrical signal is applied to a plurality of pixels.

### SUMMARY

According to an exemplary embodiment of the present invention, a thin-film transistor (TFT) substrate includes a substrate, a first TFT disposed on the substrate, and a second TFT disposed on the substrate. The first TFT includes a first active pattern having a first hydrogen density and a first gate electrode overlapping a portion of the first active pattern. The second TFT includes a second active pattern having a second hydrogen density higher than the first hydrogen density and a second gate electrode overlapping a portion of the second active pattern.

In an exemplary embodiment of the present invention, the second TFT transfers a data signal in synchronization with a scan signal, and the first TFT may output a driving current corresponding to the data signal.

In an exemplary embodiment of the present invention, the TFT substrate further includes a gate insulating layer disposed between the first active pattern and the first gate electrode and between the second active pattern and the second gate electrode to insulate the first active pattern from the first gate electrode and to insulate the second active pattern from the second gate electrode. The gate insulating layer includes a first contact hole disposed on the first active pattern and a second contact hole disposed on the second active pattern.

According to an exemplary embodiment of the present invention, a display apparatus includes the TFT substrate and a display element disposed on the TFT substrate.

According to an exemplary embodiment of the present invention, a method of manufacturing a TFT substrate includes forming a first TFT on a substrate. The first TFT includes a first active pattern and a first gate electrode overlapping a portion of the first active pattern. A second TFT is formed on the substrate. The second TFT includes a second active pattern and a second gate electrode overlapping a portion of the second active pattern. An insulating layer is formed on the first TFT and the second TFT. A first contact hole is formed in the insulating layer to expose a portion of the first active pattern. A second contact hole is formed in the insulating layer to expose a portion of the second active pattern. The first contact hole is annealed at a first temperature and the second contact hole is annealed at a second temperature that is lower than the first temperature.

In an exemplary embodiment of the present invention, the second TFT transfers a data signal in synchronization with a scan signal, and the first TFT outputs a driving current corresponding to the data signal.

In an exemplary embodiment of the present invention, the method further includes forming a gate insulating layer between the first active pattern and the first gate electrode and between the second active pattern and the second gate electrode to insulate the first active pattern from the first gate electrode and to insulate the second active pattern from the second gate electrode. The gate insulating layer includes a first contact hole disposed on the first active pattern and a second contact hole disposed on the second active pattern.

In an exemplary embodiment of the present invention, the first temperature is 10° Celsius to 50° Celsius higher than the second temperature.

In an exemplary embodiment of the present invention, the method further includes forming a first electrode of a display element connected to a drain area of the first active pattern.

According to an exemplary embodiment of the present invention, a method of manufacturing a display apparatus includes forming the TFT substrate according to the manufacturing method and forming a display element on the TFT substrate.

According to an exemplary embodiment of the present invention, a display apparatus includes a pixel disposed on a substrate. The pixel includes a first TFT, a second TFT, and an organic light-emitting diode (OLED) connected to the first TFT. The first TFT includes a first active pattern with a first hydrogen density and a first gate electrode overlapping a portion of the first active pattern. The second TFT includes a second active pattern with a second hydrogen density that is higher than the first hydrogen density and a second gate electrode overlapping a portion of the second active pattern.

In an exemplary embodiment of the present invention, the second TFT transfers a data signal in synchronization with a scan signal, and the first TFT outputs a driving current corresponding to the data signal.

In an exemplary embodiment of the present invention, the pixel further includes a gate insulating layer disposed between the first active pattern and the first gate electrode and between the second active pattern and the second gate electrode. The gate insulating layer includes a first contact hole disposed on the first active pattern and a second contact hole disposed on the second active pattern.

In an exemplary embodiment of the present invention, a first electrode of the pixel is connected to a drain area of the first active pattern.

In an exemplary embodiment of the present invention, the first contact hole is filled with a conductive material and the first electrode is disposed on the conductive material.

In an exemplary embodiment of the present invention, the OLED includes an emission layer disposed on the first electrode and a second electrode is disposed on the emission layer.

### BRIEF DESCRIPTION OF THE DRAWINGS

The above and other features of the present invention will become more apparent by describing in detail exemplary embodiments thereof with reference to the accompanying drawings, in which:

FIG. 1 is a top view of a thin-film transistor (TFT) substrate, according to an exemplary embodiment of the present invention;

FIG. 2 is a cross-sectional view of the TFT substrate of FIG. 1 along line II-II, according to an exemplary embodiment of the present invention;

FIG. 3 is a top view of a TFT substrate, according to an exemplary embodiment of the present invention;

FIG. 4 is a cross-sectional view of the TFT substrate of FIG. 3 along line V-V, according to an exemplary embodiment of the present invention; and

FIGS. 5 to 7 are cross-sectional views illustrating a method of manufacturing a TFT substrate, according to an exemplary embodiment of the present invention, and a method of manufacturing a display apparatus, according to an exemplary embodiment of the present invention.

### DETAILED DESCRIPTION OF THE EMBODIMENTS

Exemplary embodiments of the present invention will be described more fully hereinafter with reference to the accompanying drawings. Like reference numerals may refer to like elements throughout the specification. The present invention may be embodied in different forms and should not be construed as being limited to the embodiments set forth herein.

As used herein, the singular forms “a,” “an” and “the” are intended to include the plural forms as well, unless the context indicates otherwise.

It will be understood that when a layer, region, or component is referred to as being “formed on,” another layer, region, or component, the layer, region, or component may be formed on the other layer, region, or component, or intervening layers, regions, or components may be present.

When a certain exemplary embodiment of the present invention may be implemented differently, a specific process order may be performed differently from the described order. For example, two consecutively described processes may be performed substantially at the same time or performed in an order opposite to the described order.

As used herein, the term “and/or” may include any and all combinations of one or more of the associated listed items.

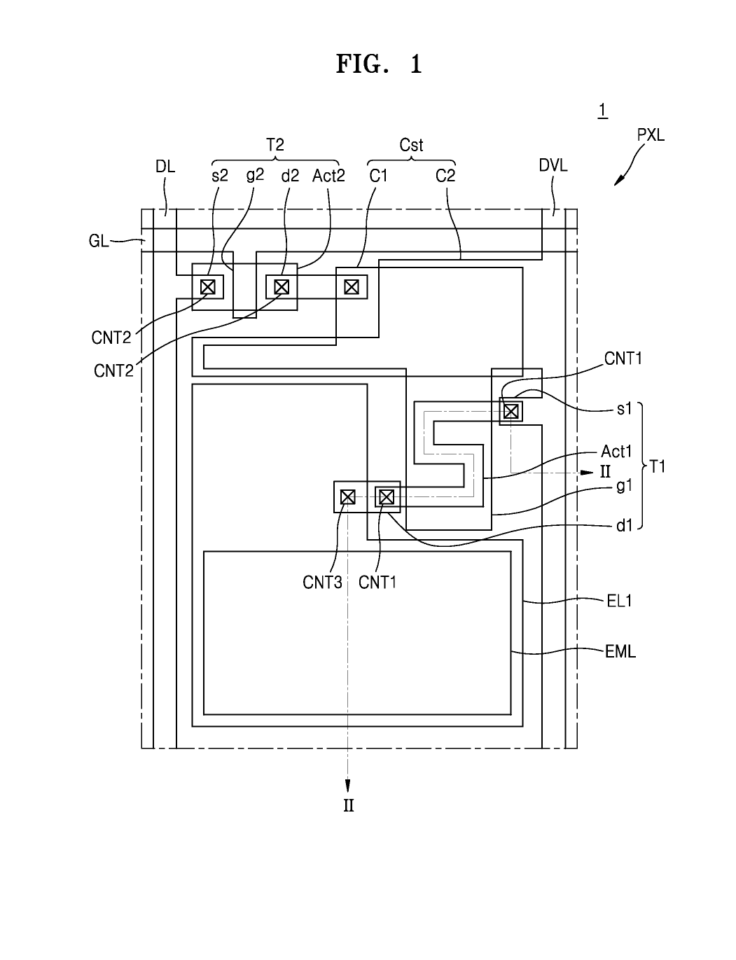

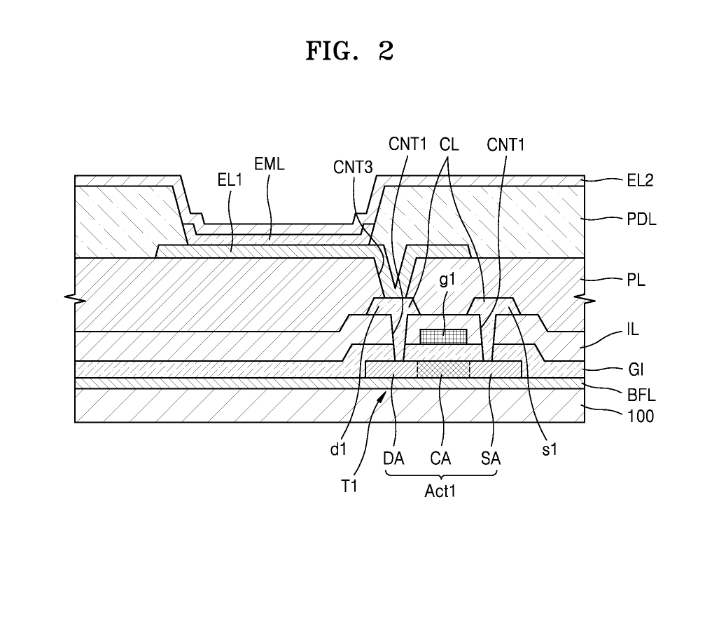

FIG. 1 is a top view of a thin-film transistor (TFT) substrate, according to an exemplary embodiment of the present invention. FIG. 2 is a cross-sectional view of the TFT substrate of FIG. 1 along line II-II, according to an exemplary embodiment of the present invention.

Referring to FIGS. 1 and 2, a TFT substrate 1, according to an exemplary embodiment of the present invention, may include a substrate 100, and a first TFT T1 and a second TFT T2.

The substrate 100 may be formed of any of various materials, such as a glass material, a metallic material, or a plastic material such as polyethylene terephthalate (PET), polyethylene naphthalate (PEN), or polyimide. The substrate 100 may have a display area in which a plurality of pixels PXL are disposed and a surrounding area surrounding the display area.

At least one pixel PXL for displaying an image is provided on the substrate 100. A plurality of pixels PXL may be provided and arranged in a matrix form, but only one pixel PXL is shown in an exemplary embodiment of the present invention for convenience of description. Although FIG. 1 shows that a pixel PXL has a rectangular shape, the present invention is not limited thereto. The pixels PXL may be modified to have various shapes. In addition, the pixels PXL may have different sizes. When the pixels PXL emit different color lights, the pixels PXL may have with different sizes or different shapes according to their colors.

The pixel PXL may include a wiring unit including a gate line GL, a data line DL, a driving voltage line DVL, the first and second TFTs T1 and T2 connected to the wiring unit, and an organic light-emitting diode (OLED) connected to the first and second TFTs T1 and T2, and a capacitor Cst.

The gate line GL may extend in a first direction, and the data line DL may extend in a second direction which crosses the first direction. The driving voltage line DVL may extend in substantially the same direction as the data line DL. The gate line GL may transfer a scan signal to a TFT, the data line DL may transfer a data signal to the TFT, and the driving voltage line DVL may transfer a driving voltage to the TFT.

According to an exemplary embodiment of the present invention, the TFT includes the first and second TFTs T1 and T2. The first TFT T1 may correspond to a driving TFT for controlling the OLED, and the second TFT T2 may correspond to a switching TFT for switching the first TFT T1 on or off. Although in an exemplary embodiment of the present invention it is described that one pixel PXL includes two TFTs (e.g., the first and second TFTs T1 and T2), the present invention is not limited thereto. For example, according to an exemplary embodiment of the present invention, one pixel PXL includes one TFT and a capacitor. According to an exemplary embodiment of the present invention, one pixel PXL includes three or more TFTs and two or more capacitors.

The first TFT T1 may include a first active pattern Act1, a first gate electrode g1, a first source electrode s1, and a first drain electrode d1. The first gate electrode g1 may be connected to the second TFT T2, the first source electrode s1 may be connected to the driving voltage line DVL, and the first drain electrode d1 may be connected to the OLED.

The second TFT T2 may include a second active pattern Act2, a second gate electrode g2, a second source electrode s2, and a second drain electrode d2. The second gate electrode g2 may be connected to the gate line GL, and the second source electrode s2 may be connected to the data line DL. The second drain electrode d2 may be connected to a gate electrode (e.g., the first gate electrode g1) of the first TFT T1. The second TFT T2 may transfer a data signal applied to the data line DL to the first TFT T1 in synchronization with a scan signal applied to the gate line GL. The first TFT T1 may output a driving current corresponding to the data signal.

According to an exemplary embodiment of the present invention, the first active pattern Act1 of the first TFT T1 has a first hydrogen density, and the second active pattern Act2 of the second TFT T2 has a second hydrogen density. In an exemplary embodiment, the second hydrogen density is higher than the first hydrogen density. The reason why the hydrogen density of the first active pattern Act1 of the first TFT T1 differs from that of the second active pattern Act2 of the second TFT T2 is because an annealing temperature for the first active pattern Act1 is higher than that of the second active pattern Act2 in an operation of annealing the first active pattern Act1 and the second active pattern Act2. The first active pattern Act1 and the second active pattern Act2 may be annealed after forming contact holes CNT1. Annealing is a process of heating a material and then allowing it to gradually cool down. Contact holes CNT1 may be formed through an interlayer dielectric layer IL and a gate insulating layer GI that insulates the first active pattern Act1. After forming the contact holes CNT1, a portion of the first active pattern Act1 is exposed through the contact holes CNT1. After exposing the portion of the first active pattern Act1 through the contact holes CNT1, the insulating layer GI and the first active pattern Act1 are annealed. Contact holes CNT2 may be formed through the interlayer dielectric layer IL and the gate insulating layer GI that insulates the second active pattern Act2. After forming the contact holes CNT2, a portion of the second active pattern Act2 is exposed through the contact holes CNT2. After exposing the portion of the second active pattern Act2 through the contact holes CNT2, the insulating layer GI and the second active pattern Act2 are annealed. In the annealing operation, the annealing temperature for the first active pattern Act1 of the first TFT T1 is about 10° Celsius to about 50° Celsius higher than that of the second active pattern Act2 of the second TFT T2. By doing this, the first active pattern Act1 of the first TFT T1 undergoes annealing at a higher temperature than the second active pattern Act2 of the second TFT T2. Accordingly, hydrogen ions trapped in the first active pattern Act1 are released into the air. Therefore, the first hydrogen density of the first active pattern Act1 of the first TFT T1 may be lower than the second hydrogen density of the second active pattern Act2 of the second TFT T2.

The first TFT T1 needs to have a wide driving range to operate as a driving TFT. The wider the driving range of the first TFT T1, the more a stain reduction effect in a display apparatus having a high resolution increases. Due to the release of more hydrogen ions due to an annealing operation of a high temperature, an interface trap density (Dit) value of the first TFT T1 increases, which causes a decrease in mobility of the first TFT T1. Thus, the properties of the first TFT T1 may be controlled so that the first TFT T1 has a wide driving range.

A display element may be disposed on the TFT substrate 1. Although it is described that the display element used in an exemplary embodiment of the present invention with reference to FIGS. 1 and 2 is an OLED, the present invention is not limited thereto. For example, according to an exemplary embodiment of the present invention, a liquid crystal element may be disposed on the TFT substrate 1 to display an image. The OLED may include an emission layer EML and first and second electrodes EL1 and EL2 facing each other with the emission layer EML interposed therebetween. The first electrode EL1 may be connected to the first drain electrode d1 of the first TFT T1. A common voltage is applied to the second electrode EL2, and the emission layer EML may emit light according to an output signal of the first TFT T1 to display an image.

The capacitor Cst may be connected between the first gate electrode g1 and the first source electrode s1 of the first TFT T1 and may charge and maintain a data signal input to the first gate electrode g1 of the first TFT T1.

A stacking sequence of the TFT substrate 1, according to an exemplary embodiment of the present invention, will now be described with reference to FIG. 2.

The TFT substrate 1, according to an exemplary embodiment of the present invention, may include the substrate 100, on which the first and second TFTs T1 and T2 and the capacitor Cst are stacked. A liquid crystal element, the OLED, or the like, may be disposed on the TFT substrate 1. According to an exemplary embodiment of the present invention, a structure in which the OLED is disposed on the TFT substrate 1 is described as an example.

The top view of the TFT substrate 1 shown in FIG. 1 is illustrative and may be variously modified.

Referring to FIG. 2, a buffer layer BFL may be disposed on the substrate 100. The buffer layer BFL may function to planarize an upper surface of the substrate 100 or to prevent the spread of impurities into the first TFT T1. The buffer layer BFL may be formed of, for example, silicon nitride, silicon oxide, silicon oxynitride, or the like, and may be omitted depending on a material included in the substrate 100 and process conditions of the substrate 100.

The first active pattern Act1 may be disposed on the buffer layer BFL. The first active pattern Act1 may be formed of a semiconductor material and may include amorphous silicon, polycrystalline silicon, or an organic semiconductor material. The first active pattern Act1 may act as an active layer of the first TFT T1. The first active pattern Act1 may include a source area SA, a drain area DA, and a channel area CA provided between the source area SA and the drain area DA. The source area SA and the drain area DA of the first active pattern Act1 may be doped with n-type impurities or p-type impurities.

The gate insulating layer GI may be disposed on the first active pattern Act1. The gate insulating layer GI may be formed of, for example, silicon oxide and/or silicon nitride, or the like, to insulate the first active pattern Act1 and the first gate electrode g1.

The first gate electrode g1 may be disposed on the gate insulating layer GI. The first gate electrode g1 may overlap at least a portion of the first active pattern Act1. For example, the first gate electrode g1 may be disposed on the gate insulating layer GI to cover an area corresponding to the channel area CA of the first active pattern Act1. The first gate electrode g1 may be formed of a metallic material by taking into account a conductivity of the metallic material, and the like.

The interlayer dielectric layer IL may be disposed on the first gate electrode g1 to cover the first gate electrode g1. The interlayer dielectric layer IL may be formed of a material such as silicon oxide, silicon nitride, or the like, and formed in a single layer or in a plurality of layers.

The interlayer dielectric layer IL may have at least one contact hole CNT1 filled with a conductive material. The conductive material filled in the at least one contact hole CNT1 may be referred to as a conductive layer CL forming the first source electrode s1 and the first drain electrode d1 of the first TFT T1. The first electrode EL1 of the OLED may be electrically connected to the first TFT T1 through the conductive material filled in the at least one contact hole CNT1.

The first source electrode s1 and the first drain electrode d1 formed as the conductive layer CL may be disposed on the interlayer dielectric layer IL. Referring to FIG. 1, the first source electrode s1 and the first drain electrode d1, respectively, are in contact with the source area SA and the drain area DA of the first active pattern Act1, respectively, through the contact holes CNT1 formed in the gate insulating layer GI and the interlayer dielectric layer IL. The second source electrode s2 and the second drain electrode d2, respectively, are in contact with a source area and a drain area of the second active pattern Act2, respectively, through contact holes CNT2 formed in the gate insulating layer GI and the interlayer dielectric layer IL.

The first source electrode s1 and the first drain electrode d1 may be formed of one or more materials among, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The first source electrode s1 and the first drain electrode d1 may be formed in a single layer or in a plurality of layers.

A portion of the first gate electrode g1 and a portion of the driving voltage line DVL, respectively, may be a first capacitor electrode C1 and a second capacitor electrode C2, respectively, and may form the capacitor Cst with the interlayer dielectric layer IL interposed therebetween. The first capacitor electrode C1 is an upper electrode of the capacitor Cst and the second capacitor electrode C2 is a lower electrode of the capacitor Cst.

A planarization layer PL may be disposed on the first source electrode s1 and the first drain electrode d1. The planarization layer PL may be disposed to cover the interlayer dielectric layer IL and the conductive layer CL. The planarization layer PL may be formed of, for example, an acrylic organic material or an organic insulating material such as benzocyclobutene (BCB), or the like. The planarization layer PL may act as a protection layer for protecting the first and second TFTs T1 and T2 or as a planarization layer for planarizing the upper surfaces thereof.

According to an exemplary embodiment of the present invention, the first active pattern Act1 of the first TFT T1 has the first hydrogen density, and the second active pattern Act2 of the second TFT T2 has the second hydrogen density. In an exemplary embodiment, the second hydrogen density is higher than the first hydrogen density. The reason why the hydrogen density of the first active pattern Act1 of the first TFT T1 differs from that of the second active pattern Act2 of the second TFT T2 is because the annealing temperature for the first active pattern Act1 is higher than that of the second active pattern Act2. The first active pattern Act1 and the second active pattern Act2 are annealed after forming the contact holes CNT1.

The contact holes CNT1 may be formed through the interlayer dielectric layer IL and the gate insulating layer GI that insulates the first active pattern Act1. After forming the contact holes CNT1, a portion of the first active pattern Act1 is exposed through the contact holes CNT1. After exposing the portion of the first active pattern Act1 through the contact holes CNT1, the insulating layer GI and the first active pattern Act1 are annealed. Contact holes CNT2 may be formed through the interlayer dielectric layer IL and the gate insulating layer GI that insulates the second active pattern Act2. After forming the contact holes CNT2, a portion of the second active pattern Act2 is exposed through the contact holes CNT2. After exposing the portion of the second active pattern Act2 through the contact holes CNT2, the insulating layer GI and the second active pattern Act2 are annealed. In the annealing operation, the annealing temperature for the first active pattern Act1 of the first TFT T1 is about 10° Celsius to about 50° Celsius higher than that of the second active pattern Act2 of the second TFT T2. By doing this, the first active pattern Act1 of the first TFT T1 undergoes annealing at a higher temperature than the second active pattern Act2 of the second TFT T2. Accordingly, hydrogen ions trapped in the first active pattern Act1 are released into the air. Therefore, the first hydrogen density of the first active pattern Act1 of the first TFT T1 may be lower than the second hydrogen density of the second active pattern Act2 of the second TFT T2.

The first TFT T1 needs to have a wide driving range to operate as a driving TFT. The wider the driving range of the first TFT T1, the more a stain reduction effect in a display apparatus having a high resolution increases. Due to the release of more hydrogen ions due to an annealing operation of a high temperature, the Dit value of the first TFT T1 increases, which causes a decrease in mobility of the first TFT T1. Thus, the properties of the first TFT T1 may be controlled so that the first TFT T1 has a wide driving range.

A display element may be disposed on the TFT substrate 1. In an exemplary embodiment of the present invention, the OLED is used as the display element. The OLED may include the first electrode EL1, the second electrode EL2, and an intermediate layer including the emission layer EML disposed between the first and second electrodes EL1 and EL2.

The first electrode EL1 of the OLED may be disposed on the planarization layer PL. The first electrode EL1 may be a pixel electrode which is electrically connected to the first drain electrode d1 of the first TFT T1 through a third contact hole CNT3 formed in the planarization layer PL.

The first electrode EL1 may be formed of a material having a high work function. For bottom emission, for example, for providing an image below the substrate 100, the first electrode EL1 may include a transparent conductive layer formed of indium tin oxide (ITO), indium zinc oxide (IZO), zinc oxide (ZnO), indium tin zinc oxide (ITZO), or the like. For top emission, for example, for providing an image above the substrate 100 (e.g., above the second electrode EL2), the first electrode EL1 may include a metal reflective layer formed of Ag, Mg, Al, Pt, Pd, Au, Ni, Nd, Ir, Cr, or the like, and a transparent conductive layer formed of ITO, IZO, ZnO, ITZO, or the like.

A pixel-defining layer PDL for defining an emission area corresponding to each pixel PXL may be disposed on the substrate 100 on which the first electrode EL1, and the like, are formed. The pixel-defining layer PDL may be formed to cover the edges of the pixel PXL such that the upper surface of the first electrode EL1 is exposed.

The emission layer EML is disposed on the first electrode EL1 exposed by the pixel-defining layer PDL, and the second electrode EL2 may be disposed on the emission layer EML.

A lower common layer may be disposed between the first electrode EL1 and the emission layer EML, and an upper common layer may be disposed between the emission layer EML and the second electrode EL2. The lower common layer and the upper common layer may be commonly stacked for each pixel PXL as a carrier transport layer. The lower common layer may include a hole injection layer (HIL) and a hole transport layer (HTL). The upper common layer may include an electron injection layer (EIL) and an electron transport layer (ETL). According to an exemplary embodiment of the present invention, when the first electrode EL1 is a pixel electrode, the lower common layer, the upper common layer, and the emission layer EML may be sequentially stacked on the first electrode EL1 in the order of the HIL, the HTL, the emission layer EML, the ETL, the EIL, and the second electrode EL2. However, the present invention is not limited thereto. The stacking order of the lower common layer and the upper common layer may be variously modified as needed.

The second electrode EL2 may also be provided as a transparent electrode or as a reflective electrode. When the second electrode EL2 is formed as a transparent electrode, the second electrode EL2 may include the above-described transparent conductive materials, and when the second electrode EL2 is formed as a reflective electrode, the second electrode EL2 may include a metal reflective layer. The second electrode EL2 may be disposed on the whole surface of the substrate 100.

When the second electrode EL2 is formed as a transparent or as a translucent electrode, the second electrode EL2 may include a layer formed of a metal having a small work function, (e.g., Li, Ca, lithium fluoride (LiF)/Ca, LiF/Al, Al, Ag, Mg, or a compound thereof) and a transparent or translucent conductive layer formed of ITO, IZO, ZnO, In₂O₃, or the like. When the second electrode EL2 is formed as a reflective electrode, the second electrode EL2 may include a layer formed of Li, Ca, LiF/Ca, LiF/Al, Al, Ag, Mg, or a compound thereof. However, the configuration and materials included in the second electrode EL2 are not limited thereto and may be variously modified.

An encapsulation layer may be formed on the second electrode EL2. The encapsulation layer may have a structure in which a plurality of inorganic layers are stacked or a structure in which organic layers and inorganic layers are alternately stacked.

An encapsulation substrate (may be disposed on the second electrode EL2. The substrate 100 may be sealed by the encapsulation substrate.

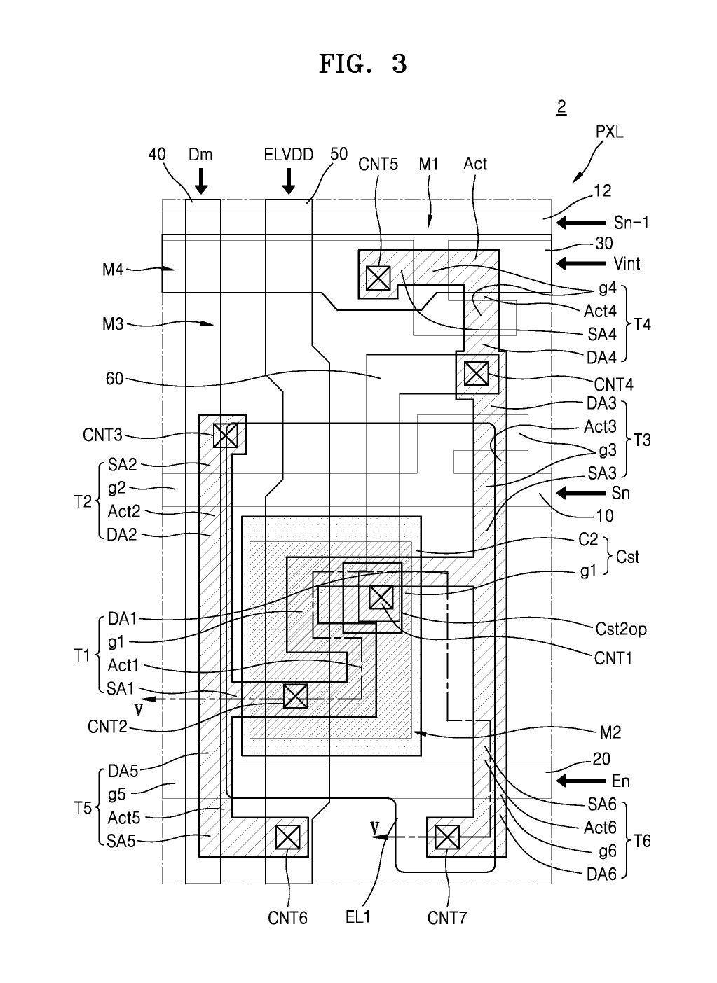

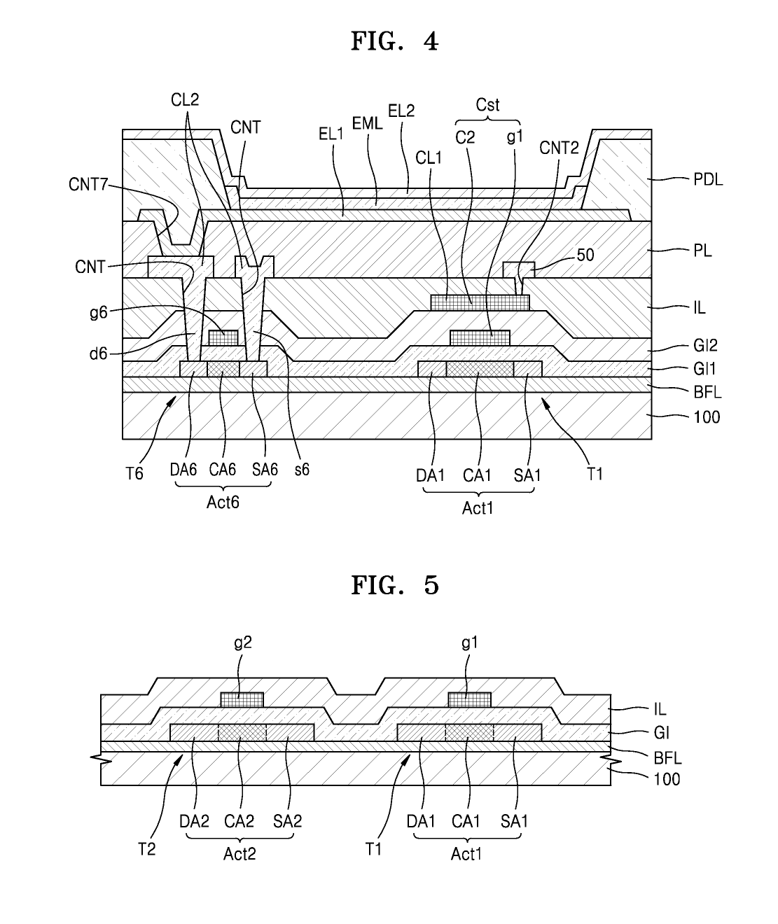

FIG. 3 is a top view of a TFT substrate, according to an exemplary embodiment of the present invention. FIG. 4 is a cross-sectional view of the TFT of FIG. 3 along line V-V, according to an exemplary embodiment of the present invention.

Referring to FIGS. 3 and 4, a TFT substrate 2, according to an exemplary embodiment of the present invention, may include the substrate 100 and the first and second TFTs T1 and T2 disposed on the substrate 100.

The substrate 100 may be formed of any of various materials, such as a glass material, a metallic material, or a plastic material such as PET, PEN, or polyimide. The substrate 100 may have a display area in which a plurality of pixels PXL are disposed and a surrounding area surrounding the display area.

At least one pixel PXL for displaying an image is provided on the substrate 100. A plurality of pixels PXL may be provided and arranged in a matrix form, but only one pixel PXL is shown in an exemplary embodiment of the present invention for convenience of description. Although FIG. 4 shows that a pixel PXL has a rectangular shape, the present invention is not limited thereto. The pixels PXL may be modified to have various shapes. In addition, the pixels PXL may have different sizes. When the pixels PXL emit different color lights, the pixels PXL may have different sizes or different shapes according to their colors.

The pixel PXL may include the first TFT T1, the second TFT T2, a third TFT T3, a fourth TFT T4, a fifth TFT T5, a sixth TFT T6, a storage capacitor Cst, and an OLED.

The first to sixth TFTs T1 to T6 may be classified according to their respective functions. The first TFT T1 is a driving TFT, the second TFT T2 is a switching TFT, the third TFT T3 is a compensation TFT, the fourth TFT T4 is an initialization TFT, the fifth TFT T5 is an operation control TFT, and the sixth TFT T6 is an emission control TFT.

The pixel PXL may include a scan line 10 through which a scan signal Sn is applied, a previous scan line 12 through which a previous scan signal Sn−1 is applied, an emission control line 20 through which an emission control signal En is applied, an initialization voltage line 30 through which an initialization voltage Vint is applied, a data line 40 through which a data signal Dm is applied, and a driving voltage line 50 through which a driving voltage ELVDD is applied. The driving voltage line 50 may be referred to as a power line 50. The scan line 10, the previous scan line 12, the emission control line 20, and the initialization voltage line 30 extend in a row direction, and the data line 40 and the driving voltage line 50 extend in a column direction.

The pixel PXL may include an active pattern Act, a first conductive layer M1, a second conductive layer M2, a third conductive layer M3, and a fourth conductive layer M4. Insulation layers may be interposed between the first conductive layer M1, the second conductive layer M2, the third conductive layer M3, and the fourth conductive layer M4. In addition, the pixel PXL may further include an intermediate layer including an emission layer and a common electrode.

The active pattern Act may include first to sixth active patterns Act1 to Act6 of the respective first to sixth TFTs T1 to T6. The first to sixth TFTs T1 to T6 may be disposed in correspondence with the active pattern Act.

Although FIG. 3 shows that the active pattern Act is formed as one pattern in one pixel PXL, the active pattern Act may be formed as two or more separated patterns. The active pattern Act may have various shapes and may have a bent portion, as shown in FIG. 3.

The first conductive layer M1 may include the previous scan line 12, the scan line 10, and the emission control line 20. In addition, the first conductive layer M1 may include first to sixth gate electrodes g1 to g6 of the respective first to sixth TFTs T1 to T6.

The second conductive layer M2 may include an upper electrode C2 of the capacitor Cst. The third conductive layer M3 may include the data line 40, the driving voltage line 50, and a connection wire 60. The fourth conductive layer M4 may include the initialization voltage line 30 and the first electrode EL1.

The active pattern Act may be formed of polysilicon and may include a channel area that is not doped with impurities and a source area and a drain area formed at both sides of the channel area which are doped with impurities. The impurities may vary depending on a type of a TFT and may be n-type impurities or p-type impurities. The active pattern Act may include a driving active pattern (e.g., the first active pattern Act1) of the driving TFT (e.g., the first TFT T1), a switching active pattern (e.g., the second active pattern Act2) of the switching TFT (e.g., the second TFT T2), a compensation active pattern (e.g., the third active pattern Act3) of the compensation TFT (e.g., the third TFT T3), an initialization active pattern (e.g., the fourth active pattern Act4 of the initialization TFT (e.g., the fourth TFT T4), an operation control active pattern (e.g., the fifth active pattern Act5) of the operation control TFT (e.g., the fifth TFT T5), and an emission control active pattern (e.g., the sixth active pattern Act6) of the emission control TFT (e.g., the sixth TFT T6).

The first TFT T1 corresponding to the driving TFT T1 may include the first active pattern Act1 and the first gate electrode g1. The first active pattern Act1 may include a channel area overlapping the first gate electrode g1, a source area SA1, and a drain area DA1. In an embodiment, the source area SA1 and the drain area DA1 do not overlap any of the first gate electrode g1 and the upper electrode C2. The first active pattern Act1 is bent.

The second conductive layer M2 including the upper electrode C2 of the capacitor Cst may be disposed on the first gate electrode g1. The upper electrode C2 may be disposed on the first gate electrode g1. The upper electrode C2 may form the capacitor Cst by overlapping the first gate electrode g1 with at least a portion thereof. The upper electrode C2 includes an opening Cst2op through which a first contact hole CNT1 connecting the first gate electrode g1 and the connection wire 60 passes. Although in FIG. 3 a shape of the opening Cst2op is shown to be a rectangle, the shape of the opening Cst2op is not limited thereto. The upper electrode C2 may maximally overlap the first gate electrode g1 except for the opening Cst2op. In this case, a maximum capacitance may be obtained.

The upper electrode C2 may form the capacitor Cst together with the first gate electrode g1. The first gate electrode g1 may also function as a lower electrode of the capacitor Cst. The upper electrode C2 may be connected to the driving voltage line 50 through a second contact hole CNT2.

The second TFT T2 corresponding to the switching TFT T2 includes the second active pattern Act2 and the second gate electrode g2 that is a portion of the scan line 10. The second active pattern Act2 may include a channel area overlapping the second gate electrode g2, and a source area SA2 and a drain area DA2 at both sides of the channel area. The source area SA2 may be connected to the data line 40 through a third contact hole CNT3. The drain area DA2 may be connected to the source area SA1 of the first TFT T1 through the active pattern Act.

The third TFT T3 corresponding to the compensation TFT T3 includes the third active pattern Act3 and the third gate electrode g3, which may be a compensation electrode, that is a portion of the scan line 10. The third active pattern Act3 may include a channel area overlapping the third gate electrode g3, and a source area SA3 and a drain area DA3 at both sides of the channel area. The source area SA3 may be connected to the drain area DA1 of the first TFT T1 through the active pattern Act. The drain area DA3 may be connected to the connection wire 60 through a fourth contact hole CNT4. For example, the drain area DA3 of the third TFT T3 is electrically connected to the first gate electrode g1 through the connection wire 60. As shown in FIG. 3, the third gate electrode g3 may be formed as a separate dual gate electrode to prevent a leakage current.

The fourth TFT T4 corresponding to the initialization TFT T4 includes the fourth active pattern Act4 and the fourth gate electrode g4, which may be an initialization electrode, that is a portion of the previous scan line 12. The fourth active pattern Act4 may include a channel area overlapping the fourth gate electrode g4, and a source area SA4 and a drain area DA4 at both sides of the channel area. The source area SA4 may be connected to the initialization voltage line 30 through a fifth contact hole CNT5. The fifth contact hole CNT5 may include a connection member formed as the third conductive layer M3, a contact hole connecting the connection member and the source area SA4, and a contact hole connecting the connection member and the initialization voltage line 30. The drain area DA4 may be connected to the connection wire 60 through the fourth contact hole CNT4. As shown in FIG. 3, the fourth gate electrode g4 may be formed as a separate dual gate electrode.

The fifth TFT T5 corresponding to the operation control TFT T5 includes the fifth active pattern Act5 and the fifth gate electrode g5, which may be an operation control electrode, that is a portion of the emission control line 20. The fifth active pattern Act5 may include a channel area overlapping the fifth gate electrode g5, and a source area SA5 and a drain area DA5 at both sides of the channel area. The drain area DA5 may be connected to the source area SA1 of the first TFT T1 through the active pattern Act. The source area SA5 may be connected to the driving voltage line 50 through a sixth contact hole CNT6.

The sixth TFT T6 corresponding to the emission control TFT T6 includes the sixth active pattern Act6 and the sixth gate electrode g6, which may be an emission control electrode, that is a portion of the emission control line 20. The sixth active pattern Act6 may include a channel area overlapping the sixth gate electrode g6, and a source area SA6 and a drain area DA6 at both sides of the channel area. The source area SA6 may be connected to the drain area DA1 of the first TFT T1 through the active pattern Act. The drain area DA6 may be connected to the first electrode EL1 through a seventh contact hole CNT7. The seventh contact hole CNT7 may include a connection member formed as the third conductive layer M3, a contact plug connecting the connection member and the drain area DA6, and a contact plug connecting the connection member and the first electrode EL1.

According to an exemplary embodiment of the present invention, the first active pattern Act1 of the first TFT T1 has the first hydrogen density, and the second active pattern Act2 of the second TFT T2 has the second hydrogen density. In an exemplary embodiment, the second hydrogen density is higher than the first hydrogen density. The reason why the hydrogen density of the first active pattern Act1 of the first TFT T1 differs from that of the second active pattern Act2 of the second TFT T2 is because an annealing temperature for the first active pattern Act1 is higher than that of the second active pattern Act2 in an operation of annealing the first active pattern Act1 and the second active pattern Act2. The first active pattern Act1 and the second active pattern Act2 may be annealed after forming the contact holes CNT1 and CNT2.

The contact holes CNT1 may be formed through the interlayer dielectric layer IL and the gate insulating layer GI that insulates the first active pattern Act1. After forming the contact holes CNT1, a portion of the first active pattern Act1 is exposed through the contact holes CNT1. After exposing the portion of the first active pattern Act1 through the contact holes CNT1, the insulating layer GI and the first active pattern Act1 are annealed. Contact holes CNT2 may be formed through the interlayer dielectric layer IL and the gate insulating layer GI that insulates the second active pattern Act2. After forming the contact holes CNT2, a portion of the second active pattern Act2 is exposed through the contact holes CNT2. After exposing the portion of the second active pattern Act2 through the contact holes CNT2, the insulating layer GI and the second active pattern Act2 are annealed. In the annealing operation, the annealing temperature for the first active pattern Act1 of the first TFT T1 is about 10° Celsius to about 50° Celsius higher than that of the second active pattern Act2 of the second TFT T2. By doing this, the first active pattern Act1 of the first TFT T1 undergoes annealing at a higher temperature than the second active pattern Act2 of the second TFT T2. Accordingly, hydrogen ions trapped in the first active pattern Act1 are released into the air. Therefore, the first hydrogen density of the first active pattern Act1 of the first TFT T1 may be lower than the second hydrogen density of the second active pattern Act2 of the second TFT T2.

The first TFT T1 needs to have a wide driving range to operate as a driving TFT. The wider the driving range of the first TFT T1, the more a stain reduction effect in a display apparatus having a high resolution increases. Due to the release of more hydrogen ions due to an annealing operation of a high temperature, the Dit value of the first TFT T1 increases, which causes a decrease in mobility of the first TFT T1. Thus, the properties of the first TFT T1 may be controlled so that the first TFT T1 has a wide driving range. The first electrode EL1 may be disposed on the upper electrode C2 and may provide a current to the intermediate layer including an organic emission layer, which is disposed thereon. The current applied to the intermediate layer is transferred to a common electrode on the intermediate layer.

The top view shown in FIG. 3 is only illustrative and may be variously modified.

A stacking sequence of the TFT substrate 2, according to an exemplary embodiment of the present invention, will now be described with reference to FIG. 4.

Referring to FIG. 4, the TFT substrate 2 according to an exemplary embodiment of the present invention, may include the substrate 100 on which the first to sixth TFTs T1 to T6, including the first TFT T1, the emission control TFT T6, and the capacitor Cst, are stacked. A liquid crystal element, the OLED, or the like, may be disposed on the TFT substrate 2. According to an exemplary embodiment of the present invention, a structure in which the OLED is disposed on the TFT substrate 2 is described as an example.

The buffer layer BFL may be disposed on the substrate 100. The buffer layer BFL may function to planarize the upper surface of the substrate 100 or to prevent the spread of impurities into the first TFT T1 and the emission control TFT T6. The buffer layer BFL may be formed of, for example, silicon nitride, silicon oxide, silicon oxynitride, or the like, and may be omitted depending on a material used in the substrate 100 and process conditions of the substrate 100.

The first TFT T1 and the emission control TFT T6 may be disposed on the buffer layer BFL. The upper electrode C2 may be disposed on the first TFT T1. The first gate electrode g1 and the upper electrode C2 form the capacitor Cst.

A lower gate insulating layer GI1 may be disposed between the active patterns Act1 and Act6 and the gate electrodes g1 and g6 to insulate the active patterns Act1 and Act6 and the gate electrodes g1 and g6. An upper gate insulating layer GI2 may be disposed between the first gate electrode g1 and the upper electrode C2 to insulate the gate electrode g1 and the upper electrode C2. The upper gate insulating layer GI2 may be a dielectric layer disposed between the first gate electrode g1 and the upper electrode C2. The first TFT T1, the capacitor Cst, and the sixth TFT T6 may be covered by the interlayer dielectric layer IL.

The lower gate insulating layer GI1 and the upper gate insulating layer GI2 may be formed in a single or in a multi-layer structure and may be formed of, for example, silicon oxide and/or silicon nitride.

According to an exemplary embodiment of the present invention, the first gate electrode g1 may be formed of a metallic material by taking into account a conductivity of the metallic material, and the like.

A first conductive layer CL1 including the upper electrode C2 of the capacitor Cst may be disposed on the upper gate insulating layer GI2. The first conductive layer CL1 of FIG. 4 may be referred to as the second conductive layer M2 of FIG. 3. The upper electrode C2 may be disposed to overlap the first gate electrode g1 with at least a portion thereof and may form the capacitor Cst together with the first gate electrode g1 by using the first gate electrode g1 as a lower electrode of the capacitor Cst.

The interlayer dielectric layer IL may be disposed on the upper electrode C2 of the capacitor Cst to cover the upper electrode C2 of the capacitor Cst. In this case, the interlayer dielectric layer IL may be an interlayer insulating layer. The interlayer dielectric layer IL may be formed of a material such as silicon oxide, silicon nitride, or the like. The interlayer dielectric layer IL may be formed in a single layer or in a plurality of layers.

The interlayer dielectric layer IL may have the second contact hole CNT2 through which a portion of the upper electrode C2 of the capacitor Cst is exposed. In addition, the interlayer dielectric layer IL may have contact holes CNT through which the source area SA6 and the drain area DA6 of the emission control active pattern Act6 of the emission control TFT T6 are exposed. The contact holes CNT may extend up to an upper portion of the emission control active pattern Act6 by penetrating through the upper gate insulating layer GI2 and the lower gate insulating layer GI1. The emission control TFT T6 is electrically connected to the first electrode EL1 of the OLED through the contact holes CNT.

A power line 50 for applying a power source voltage to the upper electrode C2 of the capacitor Cst and a second conductive layer CL2 including a source electrode s6 and a drain electrode d6 of the sixth TFT T6 may be disposed on the interlayer dielectric layer IL. The second conductive layer CL2 of FIG. 4 may be referred to as the third conductive layer M3 of FIG. 3. The upper electrode C2 of the capacitor Cst may be electrically connected to the power line 50 through a conductive material filled in the second contact hole CNT2. The power line 50 may be referred to as the driving voltage line 50. The number of contact holes CNT2 may be one or more. The second contact hole CNT2 may be variously modified.

The drain area DA6 of the sixth TFT T6 may be electrically connected to the drain electrode d6 through the contact hole CNT penetrating through all of the lower gate insulating layer GI1, the upper gate insulating layer GI2, and the interlayer dielectric layer IL. In addition, the source area SA6 of the sixth TFT T6 may be electrically connected to the source electrode s6 through the contact hole CNT penetrating through all of the lower gate insulating layer GI1, the upper gate insulating layer GI2, and the interlayer dielectric layer IL.

The second conductive layer CL2 including the driving voltage line 50, the source electrode s6, and the drain electrode d6 may be formed of a conductive material. For example, the second conductive layer CL2 may be formed of one or more materials among Al, Pt, Pd, Ag, Mg, Au, Ni, Nd, Ir, Cr, Li, Ca, Mo, Ti, W, and Cu and the second conductive layer CL2 may be formed in a single layer or in a plurality of layers.

The planarization layer PL may be disposed on the interlayer dielectric layer IL to cover the source electrode s6, the drain electrode d6, and the driving voltage line 50. The planarization layer PL may be formed of, for example, an inorganic insulating material including oxide, nitride, and/or oxynitride, an acrylic organic material, or an organic insulating material such as BCB, or the like. The planarization layer PL may act as a protection layer for protecting the first and six TFTs T1 and T6 or as a planarization layer for planarizing the upper surfaces thereof.

According to an exemplary embodiment of the present invention, the first active pattern Act1 of the first TFT T1 has the first hydrogen density, and the second active pattern Act2 of the second TFT T2 has the second hydrogen density. In an exemplary embodiment, the second hydrogen density is higher than the first hydrogen density. The reason why the hydrogen density of the first active pattern Act1 of the first TFT T1 differs from that of the second active pattern Act2 of the second TFT T2 is because the annealing temperature for the first active pattern Act1 is higher than that of the second active pattern Act2 in an operation of annealing the first active pattern Act1 and the second active pattern Act2. The first active pattern Act1 and the second active pattern Act2 may be annealed after forming the contact holes CNT1.

The contact holes CNT1 may be formed through the interlayer dielectric layer IL and the gate insulating layer GI that insulates the first active pattern Act1. After forming the contact holes CNT1, a portion of the first active pattern Act1 is exposed through the contact holes CNT1. After exposing the portion of the first active pattern Act1 through the contact holes CNT1, the insulating layer GI and the first active pattern Act1 are annealed. Contact holes CNT2 may be formed through the interlayer dielectric layer IL and the gate insulating layer GI that insulates the second active pattern Act2. After forming the contact holes CNT2, a portion of the second active pattern Act2 is exposed through the contact holes CNT2. After exposing the portion of the second active pattern Act2 through the contact holes CNT2, the insulating layer GI and the second active pattern Act2 are annealed. In the annealing operation, the annealing temperature for the first active pattern Act1 of the first TFT T1 is about 10° Celsius to about 50° Celsius higher than that of the second active pattern Act2 of the second TFT T2. By doing this, the first active pattern Act1 of the first TFT T1 undergoes annealing at a higher temperature than the second active pattern Act2 of the second TFT T2. Accordingly, hydrogen ions trapped in the first active pattern Act1 are released into the air. Therefore, the first hydrogen density of the first active pattern Act1 of the first TFT T1 may be lower than the second hydrogen density of the second active pattern Act2 of the second TFT T2.

The first TFT T1 needs to have a wide driving range to operate as a driving TFT. The wider the driving range of the first TFT T1, the more a stain reduction effect in a display apparatus having a high resolution increases. Due to the release of more hydrogen ions due to an annealing operation of a high temperature, the Dit value of the first TFT T1 increases, which causes a decrease in mobility of the first TFT T1. Thus, the properties of the first TFT T1 may be controlled so that the first TFT T1 has a wide driving range.

A display element may be disposed on the TFT substrate 2. In an exemplary embodiment of the present invention, the OLED is used as the display element. The OLED may include the first electrode EL1, the second electrode EL2, and an intermediate layer including the emission layer EML disposed between the first and second electrodes EL1 and EL2.

The first electrode EL1 of the OLED may be disposed on the planarization layer PL. The first electrode EL1 may be a pixel electrode which is electrically connected to the drain electrode d6 of the emission control TFT T6 through the seventh contact hole CNT7 formed in the planarization layer PL.

The first electrode EL1 may be formed of a material having a high work function. For bottom emission, for example, for providing an image in the lower direction of the substrate 100, the first electrode EL1 may include a transparent conductive layer formed of ITO, IZO, ZnO, ITZO, or the like. For top emission, for example, for providing an image in the upper direction of the substrate 100, the first electrode EL1 may include a metal reflective layer formed of Ag, Mg, Al, Pt, Pd, Au, Ni, Nd, Ir, Cr, or the like, and a transparent conductive layer formed of ITO, IZO, ZnO, ITZO, or the like.

The pixel-defining layer PDL for defining an emission area corresponding to each pixel PXL may be disposed on the substrate 100 on which the first electrode EL1, and the like, are formed. The pixel-defining layer PDL may be formed to cover the edges of the pixel PXL such that the upper surface of the first electrode EL1 is exposed.

The emission layer EML is disposed on the first electrode EL1 exposed by the pixel-defining layer PDL, and the second electrode EL2 may be disposed on the emission layer EML.

The emission layer EML may emit light of a color selected from among red, green, and blue colors. In addition, the emission layer EML may emit white light. A display apparatus may further include color filter layers of red, green, and blue colors to display an image of various colors.

A lower common layer may be disposed between the first electrode EL1 and the emission layer EML. An upper common layer may be disposed between the emission layer EML and the second electrode EL2. The lower common layer and the upper common layer may be commonly stacked for each pixel PXL as a carrier transport layer. The lower common layer may include an HIL and an HTL, and the upper common layer may include an EIL and an ETL. According to an exemplary embodiment of the present invention, when the first electrode EL1 is a pixel electrode, the lower common layer, the upper common layer, and the emission layer EML may be sequentially stacked on the first electrode EL1 in the order of the HIL, the HTL, the emission layer EML, the ETL, the EIL, and the second electrode EL2. However, the present invention is not limited thereto. The lower common layer and the upper common layer may be variously modified as needed.

The second electrode EL2 may be stacked on the whole surface of the substrate 100. In this case, the second electrode EL2 may be provided as a transparent electrode or as a reflective electrode. When the second electrode EL2 is used as a transparent electrode, the second electrode EL2 may include a first layer formed of Li, Ca, LiF/Ca, LiF/Al, Al, Ag, Mg, or a compound thereof, and a second layer formed on the first layer and including ITO, IZO, ZnO, In₂O₃, or the like. In this case, the second layer may be formed as an auxiliary electrode or as a bus electrode line. When the electrode EL2 is used as a reflective electrode, the second electrode EL2 may be formed by depositing Li, Ca, LiF/Ca, LiF/Al, Al, Ag, Mg, or a compound thereof, on the whole surface of the substrate 100.

An encapsulation layer may be formed on the second electrode EL2. The encapsulation layer may have a structure in which a plurality of inorganic layers are stacked or a structure in which organic layers and inorganic layers are alternately stacked.

An encapsulation substrate may be disposed on the second electrode EL2. The substrate 100 may be sealed by the encapsulation substrate.

A TFT substrate and a display apparatus including the same have been described above. However, the present invention is not limited thereto. For example, the present invention also encompasses methods for manufacturing the TFT substrate and the display apparatus including the same.

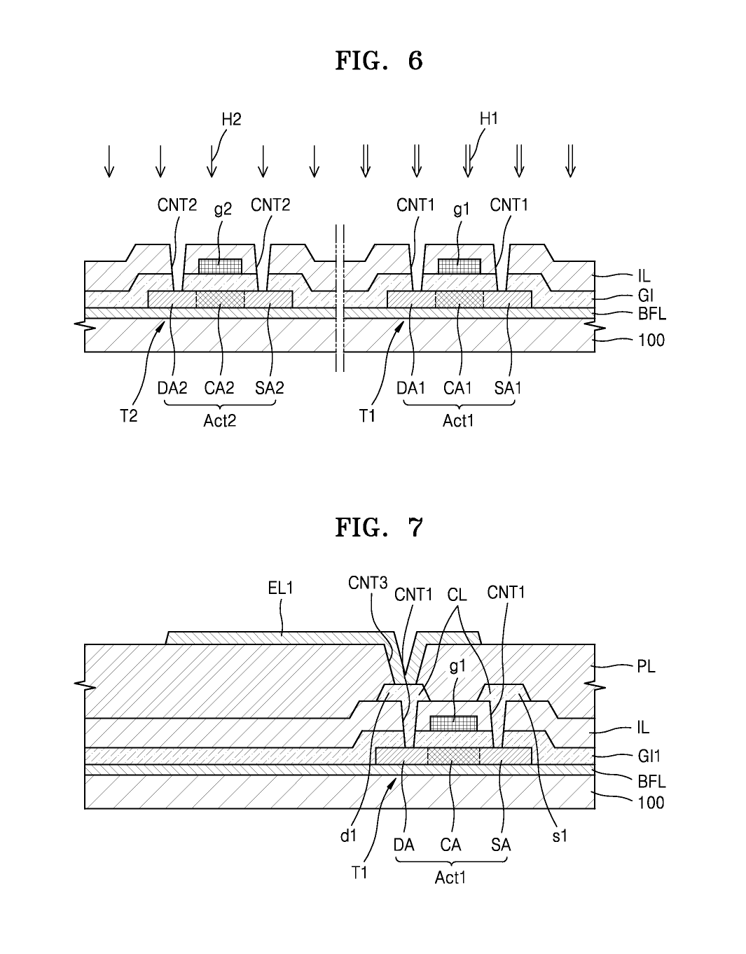

FIGS. 5 to 7 are cross-sectional views illustrating a method of manufacturing a TFT substrate, according to an exemplary embodiment of the present invention, and a method of manufacturing a display apparatus, according to an exemplary embodiment of the present invention.

Referring to FIG. 5, the first TFT T1 and the second TFT T2 may be formed on the substrate 100. The buffer layer BFL may be formed on the substrate 100 before forming the first and second TFTs T1 and T2. The buffer layer BFL may function to planarize the substrate 100 and to prevent an inflow of impurities into the first and second TFTs T1 and T2 and the first and second active patterns Act1 and Act2. The buffer layer BFL may be formed of, for example, silicon nitride, silicon oxide, silicon oxynitride, or the like. The buffer layer BFL may be omitted depending on a material included in the substrate 100 and process conditions of the substrate 100.

Then, the first active pattern Act1 of the first TFT T1 and the second active pattern Act2 of the second TFT T2 may be formed on the buffer layer BFL. The first active pattern Act1 and the second active pattern Act2 may be formed of a semiconductor material and may include amorphous silicon, polycrystalline silicon, or an organic semiconductor material. The first active pattern Act1 acts as an active layer of the first TFT T1, and the second active pattern Act2 acts as an active layer of the second TFT T2. The first active pattern Act1 may include a source area SA1, a drain area DA1, and a channel area CA1 disposed between the source area SA1 and the drain area DA1. The second active pattern Act1 may include a source area SA2, a drain area DA2, and a channel area CA2 disposed between the source area SA2 and the drain area DA2. The source areas SA1 and SA2 and the drain areas DA1 and DA2 of the first and second active patterns Act1 and Act2 may be doped with n-type impurities or p-type impurities.

The gate insulating layer GI may be formed on the first active pattern Act1 of the first TFT T1 and the second active pattern Act2 of the second TFT T2. The gate insulating layer GI may be formed of, for example, silicon oxide and/or silicon nitride, or the like, to insulate the first active pattern Act1 and the first gate electrode g1.

The first and second gate electrodes g1 and g2 may be formed on the gate insulating layer GI. The first gate electrode g1 may overlap at least a portion of the first active pattern Act1, and the second gate electrode g2 may overlap at least a portion of the second active pattern Act2. The first and second gate electrodes g1 and g2 may be formed of a metallic material by taking into account a conductivity of the metallic material, and the like.

The interlayer dielectric layer IL may be formed on the first and second gate electrodes g1 and g2 to cover the first and second gate electrodes g1 and g2. In this case, the interlayer dielectric layer IL may be an interlayer insulating layer. The interlayer dielectric layer IL may be formed of a material such as silicon oxide, silicon nitride, or the like, and may be formed in a multi-layer structure.

Then, referring to FIG. 6, at least one first contact hole CNT1 and at least one second contact hole CNT2 filled with a conductive material may be formed in the interlayer dielectric layer IL. The first contact hole CNT1 may expose at least a portion of the first active pattern Act1 (e.g., a portion of the drain area DA1 or the source area SA1 of the first active pattern Act1). The second contact hole CNT2 may expose at least a portion of the second active pattern Act2 (e.g., a portion of the drain area DA2 or the source area SA2 of the second active pattern Act2).

After forming the at least one first contact hole CNT1 and the at least one second contact hole CNT2, an annealing operation of applying heat to or heating the interlayer dielectric layer IL is performed. In the annealing operation, the first TFT T1 and the second TFT T2 are heat-treated at different temperatures, respectively. For example, the at least one first contact hole CNT1 is heat-treated at a first temperature H1 for the first active pattern Act1 of the first TFT T1, and the at least one second contact hole CNT2 is heat-treated at a second temperature H2 for the second active pattern Act2 of the second TFT T2.

In this operation, the first temperature H1 for the first active pattern Act1 of the first TFT T1 is about 10° Celsius to about 50° Celsius higher than the second temperature H2 for the second active pattern Act2 of the second TFT T2. By doing this, the first active pattern Act1 of the first TFT T1 undergoes an annealing operation at a higher temperature than the second active pattern Act2 of the second TFT T2. As a result of the annealing at the higher temperature, hydrogen ions trapped in the first active pattern Act1 are released into the air. Therefore, the first hydrogen density of the first active pattern Act1 of the first TFT T1 may be lower than the second hydrogen density of the second active pattern Act2 of the second TFT T2.

The first TFT T1 needs to have a wide driving range to operate as a driving TFT. The wider the driving range of the first TFT T1, the more a stain reduction effect in a display apparatus having a high resolution increases. Due to the release of more hydrogen ions due to an annealing operation of a high temperature, the Dit value of the first TFT T1 increases, which causes a decrease in mobility of the first TFT T1. Thus, the properties of the first TFT T1 may be controlled so that the first TFT T1 has a wide driving range.

Then, referring to FIG. 7, the first source electrode s1 and the first drain electrode d1 may be formed to be electrically connected to the first active pattern Act1 through the conductive material filled in the at least one first contact hole CNT1 of the first TFT T1. In addition, the second source electrode s2 and the second drain electrode d2 may be formed to be electrically connected to the second active pattern Act2 through the conductive material filled in the at least one second contact hole CNT2 of the second TFT T2. The first and second source electrodes s1 and s2 and the first and second drain electrodes d1 and d2 may be formed of a metallic material by taking into account a conductivity of the metallic material, and the like.

Then, the planarization layer PL may be formed on the first and second source electrodes s1 and s2 and the first and second drain electrodes d1 and d2 to cover the first and second source electrodes s1 and s2 and the first and second drain electrodes d1 and d2. The planarization layer PL may be formed to cover the interlayer dielectric layer IL, the first and second source electrodes s1 and s2, and the first and second drain electrodes d1 and d2. The planarization layer PL may be formed of, for example, an acrylic organic material or an organic insulating material such as BCB, or the like. The planarization layer PL may act as a protection layer for protecting the first and second TFTs T1 and T2 or as a planarization layer for planarizing the upper surfaces thereof.

Then, the third contact hole CNT3 may be formed in the planarization layer PL. The third contact hole CNT3 may electrically connect the first source electrode s1 or the first drain electrode d1 of the first TFT T1 to the first electrode EL1. Thereafter, the OLED including the first electrode EL1, the emission layer EML, and the second electrode EL2 may be formed. The OLED is the same as described above. Thus, the OLED is not described again.

As described above, according to one or more exemplary embodiments of the present invention, a TFT substrate capable of adjusting characteristics depending on functions of TFTs disposed thereon, a display apparatus including the same, a method of manufacturing the TFT substrate, and a method of manufacturing the display apparatus may be implemented. However, the scope of the present invention is not limited thereto.

Descriptions of aspects within each exemplary embodiment of the present invention should be considered as applicable to other similar aspects included in other exemplary embodiments of the present invention.

While the present invention has been particularly shown and described with reference to exemplary embodiments thereof, it will be apparent to those of ordinary skill in the art that various changes in form and detail may be made therein without departing from the spirit and scope of the inventive concept.

What is claimed is:

1. A thin-film transistor (TFT) substrate comprising:
a substrate;
a first TFT disposed on the substrate, wherein the first TFT comprises a first active pattern having a first hydrogen density and a first gate electrode overlapping a portion of the first active pattern; and
a second TFT disposed on the substrate, wherein the second TFT comprises a second active pattern having a second hydrogen density higher than the first hydrogen density and a second gate electrode overlapping a portion of the second active pattern.

2. The TFT substrate of claim 1, wherein the second TFT transfers a data signal in synchronization with a scan signal, and the first TFT outputs a driving current corresponding to the data signal.

3. The TFT substrate of claim 1, further comprising a gate insulating layer disposed between the first active pattern and the first gate electrode and between the second active pattern and the second gate electrode to insulate the first active pattern from the first gate electrode and to insulate the second active pattern from the second gate electrode.
wherein the gate insulating layer comprises a first contact hole disposed on the first active pattern and a second contact hole disposed on the second active pattern.

4. A display apparatus comprising:
the TFT substrate of claim 1; and
a display element disposed on the TFT substrate.

5. A display apparatus comprising:
the TFT substrate of claim 2; and
a display element disposed on the TFT substrate.

6. A display apparatus comprising:
the TFT substrate of claim 3; and
a display element disposed on the TFT substrate.

7. A method of manufacturing a thin-film transistor (TFT) substrate, the method comprising:
forming a first TFT on a substrate, the first TFT including a first active pattern and a first gate electrode overlapping a portion of the first active pattern;
forming a second TFT on the substrate, the second TFT including a second active pattern and a second gate electrode overlapping a portion of the second active pattern;
forming an insulating layer on the first TFT and the second TFT;
forming a first contact hole in the insulating layer to expose a portion of the first active pattern;
forming a second contact hole in the insulating layer to expose a portion of the second active pattern; and
annealing the first contact hole at a first temperature and annealing the second contact hole at a second temperature that is lower than the first temperature.

8. The method of claim 7, wherein the second TFT transfers a data signal in synchronization with a scan signal, and the first TFT outputs a driving current corresponding to the data signal.

9. The method of claim 7, further comprising forming a gate insulating layer between the first active pattern and the first gate electrode and between the second active pattern and the second gate electrode to insulate the first active pattern from the first gate electrode and to insulate the second active pattern from the second gate electrode,
wherein the gate insulating layer comprises the first contact hole disposed on the first active pattern and the second contact hole disposed on the second active pattern.

10. The method of claim 7, wherein the first temperature is 10° Celsius to 50° Celsius higher than the second temperature.

11. The method of claim 7, further comprising forming a first electrode of a display element connected to a drain area of the first active pattern.

12. A method of manufacturing a display apparatus, the method comprising:
forming the TFT substrate according to the manufacturing method of claim 7; and
forming a display element on the TFT substrate.

13. A method of manufacturing a display apparatus, the method comprising:
forming the TFT substrate according to the manufacturing method of claim 8; and
forming a display element on the TFT substrate.

14. A method of manufacturing a display apparatus, the method comprising:
forming the TFT substrate according to the manufacturing method of claim 9; and
forming a display element on the TFT substrate.

15. A display apparatus comprising:
a pixel disposed on a substrate, the pixel comprising:
a first TFT disposed on the substrate, wherein the first TFT comprises a first active pattern with a first hydrogen density and a first gate electrode overlapping a portion of the first active pattern;
a second TFT disposed on the substrate, wherein the second TFT comprises a second active pattern with a second hydrogen density that is higher than the first hydrogen density and a second gate electrode overlapping a portion of the second active pattern; and
an organic light-emitting diode (OLED) connected to the first TFT.

16. The display apparatus of claim 15, wherein the second TFT transfers a data signal in synchronization with a scan signal, and the first TFT outputs a driving current corresponding to the data signal.

17. The display apparatus of claim 15, wherein the pixel further comprises a gate insulating layer disposed between the first active pattern and the first gate electrode and between the second active pattern and the second gate electrode,
wherein the gate insulating layer comprises a first contact hole disposed on the first active pattern and a second contact hole disposed on the second active pattern.

18. The display apparatus of claim 17, wherein a first electrode of the pixel is connected to a drain area of the first active pattern.

19. The display apparatus of claim 18, wherein the first contact hole is filled with a conductive material and the first electrode is disposed on the conductive material.

20. The display apparatus of claim 18, wherein the OLED comprises an emission layer disposed on the first electrode, and
wherein a second electrode is disposed on the emission layer.
